(19) United States
(12) Patent Application Publication
(10) Pub. No.: US 2025/0389868 A1
(43) Pub. Date: Dec. 25, 2025

(54) NANOOPTICS WITH HIGH REFRACTIVE INDEX APERTURES

(71) Applicant: PRESIDENT AND FELLOWS OF HARVARD COLLEGE, Cambridge, MA (US)

(72) Inventors: Marcus Tobias Ossiander, Cambridge, MA (US); Maryna Leonidivna Meretska, Cambridge, MA (US); Soon Wei Daniel Lim, Cambridge, MA (US); Federico Capasso, Cambridge, MA (US)

(73) Assignee: PRESIDENT AND FELLOWS OF HARVARD COLLEGE, Cambridge, MA (US)

(21) Appl. No.: 18/878,627

(22) PCT Filed: Jun. 29, 2023
(86) PCT No.: PCT/US2023/026650

§ 371 Date: Dec. 23, 2024

Related U.S. Application Data
(60) Provisional application No. 63/358,066, filed on Jul. 1, 2022.

(51) Int. Cl. G02B 1/00; G02B 1/02; G02B 3/02

(52) U.S. Cl. CPC G02B 1/002; G02B 1/02; G02B 3/02

(57) ABSTRACT

An optical device includes a membrane. The membrane includes a plurality of apertures extending at least partially through a thickness of the membrane. The membrane is configured to structure incoming light having a wavelength to produce modified light. The wavelength of the incoming light is in a range of a wavelength of X-ray light to a wavelength of ultraviolet light. The membrane can be configured to transmit the modified light through the membrane. The membrane can be configured to reflect modified light away from the membrane. An index of refraction within a first aperture of the plurality of apertures is greater than an index of refraction of the membrane.

### CROSS-REFERENCE TO RELATED PATENT APPLICATION

This application claims the benefit and priority of U.S. Provisional Patent Application No. 63/358,066, filed on Jul. 1, 2022, the entirety of which is incorporated by reference herein.

### GOVERNMENT LICENSE RIGHTS

This invention was made with government support under FA9550-21-1-0312 awarded by U.S. Air Force Office of Scientific Research (AFOSR). The government has certain rights in this invention.

### BACKGROUND

Refractive imaging optics can be bulky and expensive, and can be restricted to single functions. In addition, they can rarely exist for the extreme ultraviolet spectrum and each refractive device can require individual optical characterization for sensitive commercial applications. Metasurface-based optics exploiting nanostructured surfaces can offer diffraction-limited, lightweight, multifunctional, and reproducible optical behavior.

### SUMMARY

The systems and methods of the present disclosure relate to a metasurface platform (e.g., metalens) which can expand the range of extreme-ultraviolet (EUV or XUV) radiation applications for semiconductor manufacturing, modern material science, and attosecond metrology. This class of dielectric metasurfaces can focus EUV radiation. The refractive index of silicon can be smaller than unity for radiation around 50 nm wavelength (e.g., 25 eV photon energy). As a result, holes in a silicon membrane can have a considerably larger refractive index than the surrounding material. This can allow for efficient vacuum-guiding of radiation as well as control of the transmission phase through the hole diameter. A vacuum-guiding metasurface with a focal length of 10 mm supporting numerical apertures up to 0.05 can be fabricated and can experimentally demonstrate efficient focusing of EUV radiation. This approach can introduce a wide range of light shaping possibilities of dielectric metasurfaces in an entirely novel spectral regime.

At least one aspect of the present disclosure is directed to an optical device. The optical device includes a membrane. The membrane includes a plurality of apertures extending at least partially through a thickness of the membrane. The membrane is configured to structure incoming light having a wavelength to produce modified light. The wavelength of the incoming light is in a range from a wavelength of X-ray light to a wavelength of ultraviolet light. The membrane is configured to transmit the modified light through the membrane. An index of refraction within a first aperture of the plurality of apertures is greater than an index of refraction of the membrane.

Another aspect of the present disclosure is directed to an optical device. The optical device includes a membrane. The membrane includes a plurality of apertures extending at least partially through a thickness of the membrane. The membrane is configured to structure incoming light having a wavelength to produce modified light. The wavelength of the incoming light is in a range from a wavelength of X-ray light to a wavelength of ultraviolet light. The membrane is configured to reflect the modified light away from the membrane. An index of refraction within a first aperture of the plurality of apertures is greater than an index of refraction of the membrane.

Those skilled in the art will appreciate that the summary is illustrative only and is not intended to be in any way limiting. Other aspects, inventive features, and advantages of the devices and/or processes described herein, as defined solely by the claims, will become apparent in the detailed description set forth herein and taken in conjunction with the accompanying drawings.

### BRIEF DESCRIPTION OF THE DRAWINGS

The details of one or more implementations of the subject matter described in this specification are set forth in the accompanying drawings and the description below. Other features, aspects, and advantages of the subject matter will become apparent from the description, the drawings, and the claims.

FIG. 1 illustrates a perspective view of a metalens, according to an embodiment.

FIG. 2 illustrates a plot of a photon energy-dependent refractive index of crystalline silicon and a plot of photon energy-dependent intensity transmission of crystalline silicon, according to an embodiment.

FIG. 3 illustrates a finite difference time domain simulation of a transverse beam intensity profile of EUV-guiding, according to an embodiment.

FIG. 4 illustrates plots of a hole diameter-dependent intensity transmission and transmission phase, according to an embodiment.

FIG. 5 illustrates a plot of a photon energy and hole diameter-dependent transmission phase of holes, according to an embodiment.

FIG. 6 illustrates a plot of a photon energy and hole diameter-dependent intensity transmission of holes, according to an embodiment.

FIG. 7 illustrates a plot of an ideal radial phase profile of a metalens compared to the intensity profile of a binary intensity Fresnel zone plate, according to an embodiment.

FIG. 8 illustrates a 2-D representation of a binary intensity Fresnel zone plate realizing the transmission profile of FIG. 7, according to an embodiment.

FIG. 9 illustrates a 2-D representation of a metalens realizing the phase profile of FIG. 7, according to an embodiment.

FIG. 10 illustrates a model of transverse intensity cuts through the focus generated by the zone plate in FIG. 8 and the metalens in FIG. 9, according to an embodiment.

FIG. 11 illustrates a model of 2-D light intensity evolution of the zone plate of FIG. 8 focusing a Gaussian beam, according to an embodiment.

FIG. 12 illustrates a model of 2-D light intensity evolution of the metalens of FIG. 9 focusing a Gaussian beam, according to an embodiment.

FIG. 13A illustrates an overhead view of a fabricated metalens, according to an embodiment.

FIG. 13B illustrates a cross-sectional view of a fabricated metalens, according to an embodiment.

FIG. 14 illustrates a large-area picture of the metalens in FIGS. 13A-13B, according to an embodiment.

FIG. 15 illustrates an experimental demonstration set-up of EUV metalens focusing, according to an embodiment.

FIG. 16 illustrates plots of knife-edge scans at different positions along the propagation direction of a beam after a metalens of an experimental demonstration of EUV metalens focusing, according to an embodiment.

FIG. 17 illustrates a plot of propagation-direction dependent focus sizes of an experimental demonstration of EUV metalens focusing, according to an embodiment.

FIG. 18 illustrates a fabrication process for a metalens, according to an embodiment.

FIGS. 19A-19D illustrate scanning electron micrographs of metalens arrays with various hole shapes, according to an embodiment.

Like reference numbers and designations in the various drawings indicate like elements.

### DETAILED DESCRIPTION

Following below are more detailed descriptions of various concepts related to, and implementations of methods and apparatuses for optical devices including a membrane (e.g., substrate, film/layer/sheet of material, which can be flexible or pliable), the membrane including a plurality of apertures (e.g., holes) extending at least partially through a thickness of the membrane. The various concepts introduced above and discussed in greater detail below may be implemented in any of a number of ways, as the described concepts are not limited to any particular manner of implementation. Examples of specific implementations and applications are provided primarily for illustrative purposes.

Metasurfaces can have multifunctionality and ability to match or exceed the performance of conventional refractive optics within a lightweight footprint. An all-glass metasurface fabricated using deep-ultraviolet (DUV) lithography can have lower monochromatic aberrations than an equivalent aspheric lens. A single metasurface can be used to turn an image sensor into a polarization camera. The uniformly flat, few-layered geometry of metasurfaces can simplify optical alignment. These surfaces can be designed with subwavelength and wavelength-scale nanostructures (e.g., meta-atoms, meta-elements, etc.) that allow the phase, amplitude, and/or polarization of incident light to be manipulated with precision. The shape of the nanostructures can produce optical responses that exceed the capabilities of the bulk material alone. The nanostructures can be fabricated using CMOS-compatible technologies and high throughput nanoimprinting methods which can enable these devices to be scaled up to high volumes reproducibly.

The strong absorption of all materials in the EUV spectrum can prevent the usage of most transmissive optical components. Thus, EUV optics can rely on bulky, expensive optics which, coupled with requirements for high-quality surfaces, low wavefront errors, and multilayer coatings, limit achievable numerical apertures. Dielectric metasurfaces can include nanostructures that manipulate the transmission or reflection phase of light on the nanoscale. The manipulation of the transmission or reflection phase of light can allow the replacement of standard optics with thin and flat optical elements that can realize multiple novel optical functions such as freely designable optical angular momentum into a single optical element.

Another hindrance for realizing transmissive optical elements in the EUV spectrum is that the index of refraction of most materials can be close to unity (e.g., index of refraction of a vacuum), over large spectral regions and can prevent effective refraction and light guiding. Although the index of refraction of most dielectric materials in the visible spectrum can be larger than unity, EUV light can oscillate faster than electronic resonance frequencies in solid, liquid, or gaseous materials. Thus, the index of refraction of materials in this region can be smaller than unity. A dielectric pillar can possess an index of refraction smaller than the surrounding vacuum, resulting in an inability to guide light. However, a void (e.g., hole, aperture, etc.) in a layer of material with an index of refraction smaller than unity can have a larger index of refraction than the surrounding material and can thus guide light. As such, holes in a membrane can be equivalent to high index nanopillars in classical metasurface design for the EUV spectrum.

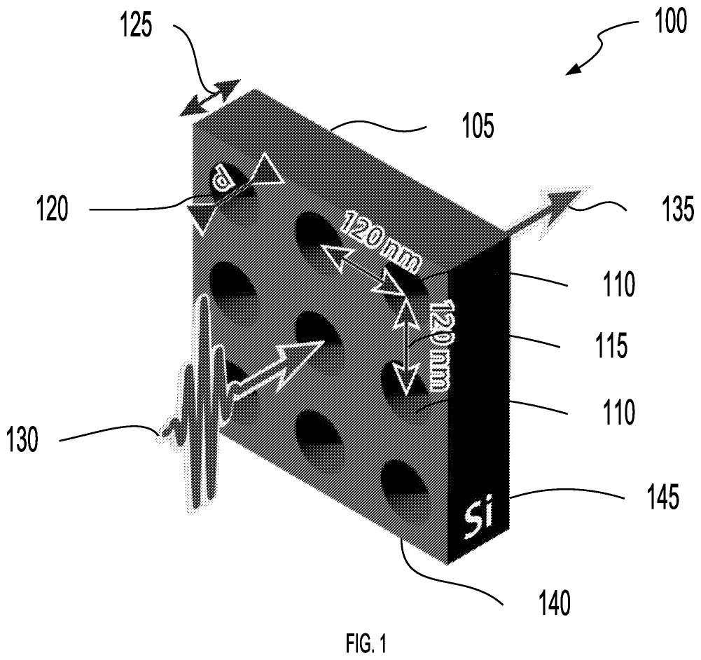

FIG. 1A illustrates a perspective view of a metalens 100. The metalens 100 can include a holey metalens (e.g., a metalens with holes or apertures and a vacuum in the holes). The metalens 100 can include at least one membrane 105. The membrane 105 can include a plurality of apertures 110 (e.g., holes, nanoholes, voids, etc.). The membrane 105 can define a plurality of apertures 110. For example, the membrane 105 can include periodic, aperiodic, or quasirandom placements of apertures 110 of varying diameter 120 and placement distance 115 between a first aperture and a second aperture. The diameter 120 can range from 20 to 80 nm (e.g., 20 nm, 30 nm, 40 nm, 50 nm, 60 nm, 70 nm, or 80 nm, inclusive). The placement distance 115 of the plurality of apertures 110 can be uniform. The placement distance 115 of the plurality of apertures 110 can also be quasirandom to reduce the strength of unwanted diffracted orders. The membrane 105 can have a thickness 125. For example, the membrane can have a thickness 125 of 220 nm. The optical wavefront of the incoming light 130 can be controlled by the structure (e.g., metalens 100, optical device, etc.) and can produce a diffraction-limited focal spot upon transmission. The incoming light 130 can be in the EUV regime (e.g., spectrum), X-ray regime, ultraviolet regime, or other wavelength regimes. Upon transmission through the membrane, the incoming light 130 can become modified light 135. A vacuum, a gaseous medium, a liquid medium, or a solid medium can be disposed into an aperture of a plurality of apertures 110. The membrane 105 can be made of silicon (e.g., crystalline silicon), aluminium, beryllium, scandium, zirconium, molybdenum, semiconductors, III-V materials, polymers, or metals.

The metalens 100 can be part of an optical device for transmission. The optical device can include a monolithic metasurface or metalens 100. The monolithic metasurface can include a metasurface made of a single material (e.g., crystalline silicon, etc.). The monolithic metasurface can be formed from a single piece of material. The optical device can operate in an X-ray to ultraviolet spectral range. The optical device can include the metalens 100 or the membrane 105. The membrane 105 can include a plurality of apertures 110 extending at least partially through a thickness 125 of the membrane 105. The membrane 105 can be configured to structure (e.g., modify, change) incoming light 130 to produce modified light 135. The incoming light 130 can have a wavelength (e.g., wavelength of the incoming light). The incoming light 130 can have one or more wavelengths. The wavelength of the incoming light 130 in vacuum (e.g., vacuum wavelength, vacuum wavelength of the incoming light) can be in a range from X-ray light to EUV light to ultraviolet light. The X-ray light can be in a wavelength range of 0.3 nm to 3 nm (e.g., 0.3 nm, 1 nm, 2 nm, or 3 nm, inclusive). The X-ray light can include soft X-rays. The EUV light can be in a wavelength range of 10 nm to 121 nm (e.g., 10 nm, 20 nm, 50 nm, 100 nm, or 121 nm, inclusive). Ultraviolet (UV) light can be in a wavelength range of 100 nm to 400 nm (e.g., 100 nm, 150 nm, 200 nm, 250 nm, 300 nm, 350 nm, or 400 nm, inclusive). The wavelength of the incoming light 130 in vacuum can be in a range of 0.3 nm to 400 nm (e.g., 0.3 nm, 1 nm, 10 nm, 20 nm, 50 nm, 100 nm, or 400 nm, inclusive). The wavelength of the incoming light 130 in vacuum can be X-ray light, EUV light, or UV light. Structuring the incoming light 130 can include modifying the phase profile, amplitude profile, or polarization profile of the incoming light 130. For example, the transmitted modified light 135 can have a different phase profile, amplitude profile, or polarization profile than that of the incoming light 130. Each of the plurality of apertures 110 can have a diameter 120 (e.g., width).

An index of refraction within a first aperture of the plurality of apertures 110 can be greater than an index of refraction of the membrane 105. For example, the index of refraction within the first aperture of the plurality of apertures 110 can include a high index of refraction. The index of refraction of the membrane 105 can include a low index of refraction. The index of refraction of the membrane 105 can be lower than the index of refraction within the first aperture of the plurality of apertures 110. The index of refraction within the first aperture can correspond to an index of refraction of the at least one of the vacuum, the gaseous medium, the liquid medium, or the solid medium. The index of refraction can include the ratio of the speed of light in a vacuum to the speed of light in a medium (e.g., gaseous medium, liquid medium, solid medium, etc.).

In some embodiments, the plurality of apertures 110 can include via-holes or through-holes. The membrane 105 can include a first surface 140 and a second surface 145. The plurality of apertures 110 can each have an opening (e.g., nano-opening, nanohole, etc.) in a plane defined by the first surface 140 and can each have another opening (e.g., nano-opening, nanohole, second opening, etc.) in a plane defined by the second surface 145. For example, the plurality of apertures 110 can go through the first surface 140 and/or through the second surface 145. The diameter 120 of the plurality of apertures 110 can control the transmitted phase of light. The openings can have radial symmetry or non-radial symmetry. A cross-sectional profile of the openings can vary through the depth of the openings. The plurality of apertures 110 can be disjoint. For example, each of the plurality of apertures can be completely separated from each other. The plurality of apertures 110 can be formed via etching or through an etching process. The membrane 105 can be formed through an etching process as opposed to an additive manufacturing process to create the membrane 105. The plurality of apertures 110 can be located within the membrane 105 as opposed to holes being located within pillars.

In some embodiments, the membrane 105 can be configured to operate in transmission of the modified light 135 as at least one of a converging lens, a diverging lens, a cylindrical lens, a corrector of optical aberrations of a second optical element, a diffraction grating, or a waveplate. For example, the membrane 105 can operate in transmission by transmitting incoming light 130 through the membrane 105. The membrane 105 can be configured to operate in transmission as a corrector of optical aberrations of a second optical element. The membrane 105 can be configured to operate in transmission as a diffraction grating. The membrane 105 can be configured to operate in transmission as a waveplate (e.g., retarder). For example, the membrane 105 can operate as a waveplate by altering the polarization of the incoming light 130. The membrane 105 can also operate as a spatially-varying waveplate by altering the polarization of incoming light 130 in a spatially-varying manner.

In some embodiments, one or more optical properties is constant at a plurality of incident wavelengths. The one or more optical properties of the membrane 105 can be constant at a plurality of incident wavelengths. The one or more optical properties of the optical device can be constant at a plurality of incident wavelengths. A phase profile of the transmitted modified light 135 can produce focusing of incident light at a plurality of wavelengths with a same focal length. For example, the optical device can exhibit achromatic behavior. The phase profile of the modified light 135 that is transmitted can produce diffracted orders with a same diffraction angle at a plurality of wavelengths. For example, the optical device can exhibit achromatic grating behavior.

In some embodiments, the modified light 135 that is transmitted includes light with at least one of a modified optical phase profile, modified amplitude profile, or modified polarization profile. The incoming light can have a first optical phase profile and the modified light can have a second optical phase profile. The first optical phase profile can be different from the second optical phase profile. The incoming light can have a first amplitude profile and the modified light can have a second amplitude profile. The first amplitude profile can be different from the second amplitude profile. The incoming light can have a first polarization profile and the modified light can have a second polarization profile. The polarization profile can include the geometric orientation of light waves. The first polarization profile can be different from the second polarization profile. The incoming light can have a first wavelength and the modified light can have a second wavelength. The first wavelength can be different from the second wavelength. The first wavelength can be the same as the second wavelength.

In some embodiments, the incoming light 130 can exert an optical force on the metalens 100. In some embodiments, the modified light 135 can exert an optical force on the metalens 100. In some embodiments, the incoming light 130 does not exert an optical force on the metalens 100. In some embodiments, the modified light 135 does not exert an optical force on the metalens 100.

In some embodiments, each of the plurality of apertures 110 can have non-cylindrical symmetry. For example, the plurality of apertures 110 can include rectangular prism structures. The cross-sectional profile of a first aperture of the plurality of apertures 110 can be constant over a length of the first aperture. In some embodiments, the cross-sectional profile of a first aperture of the plurality of apertures 110 can vary over a length of the first aperture.

In some embodiments, the plurality of apertures 110 can be periodically placed on the membrane 105. For example, the plurality of apertures 110 can be placed periodically in a square unit cell separated by the placement distance 115. Each of the plurality of apertures 110 can be separated by the placement distance 115. The plurality of apertures 110 can be periodically space in the membrane 105. The plurality of apertures 110 can be placed at regular occurring intervals.

In some embodiments, the plurality of apertures 110 can be aperiodically placed on the membrane 105. For example, the plurality of apertures 110 have a varying placement distance 115 on the membrane 105. In some embodiments, the plurality of apertures 110 can be quasirandomly placed on the membrane 105. For example, the plurality of apertures 110 have a varying placement distance 115 according to a quasirandom pattern on the membrane 105. This pattern can be generated to reduce the strength of undesirable diffracted orders.

In some embodiments, the placement distance 115 (e.g., such as aperture edge to aperture edge distance, or aperture center to aperture center distance) between each of the plurality of apertures 110 can be subwavelength relative to the wavelength of the incoming light 130. For example, the placement distance 115 between each of the plurality of apertures 110 can be less than the wavelength of the incoming light 130 in vacuum. Subwavelength can include a multiple (e.g., 0.1 times, 0.2 times, 0.3 times, 0.4 times, 0.5 times, 0.6 times, 0.7 times, 0.8 times, 0.9 times, etc.) of the wavelength of the incoming light 130 that is less than the wavelength of the incoming light 130. The placement distance 115 between each of the plurality of apertures 110 can be wavelength-scale relative to the wavelength of the incoming light 130. For example, the placement distance 115 between each of the plurality of apertures 110 can be greater than or equal to a wavelength of the incoming light 130 in vacuum. Wavelength-scale can include a multiple (e.g., 1 time, 2 times, 5 times, 10 times, etc.) of the wavelength of the incoming light 130 that is greater than or equal to the wavelength of the incoming light 130. The placement distance 115 between each of the plurality of apertures 110 can be less than, greater than, or equal to the wavelength of the incoming light 130. The placement distance 115 between each of the plurality of apertures 110 can be a distance between a first aperture outer radius and a second aperture outer radius. The aperture edge can include an outer radius of each of the plurality of apertures 110. The aperture center can include a center of each of the plurality of apertures 110. The placement distance 115 between each of the plurality of apertures can be a center of a first aperture and a center of a second aperture. The center of an aperture can be equidistant from the aperture edge. In some embodiments, the placement distance 115 between each of the plurality of apertures 110 can be relative to the wavelength of the incoming light 130. For example, the placement distance 115 between each of the plurality of apertures 110 can be equal to or more than the wavelength of the incoming light 130 in vacuum.

In some embodiments, the thickness 125 of the membrane 105 remains constant over a length or a width of the membrane 105. For example, if the thickness 125 of the membrane 105 is 220 nm, this value can remain constant across the entirety of the membrane 105. The thickness 125 of the membrane 105 can vary along a length or a width of the membrane 105.

In some embodiments, the membrane 105 is mounted onto at least one of a flat solid substrate or a curved solid substrate to provide structural support. For example, the metalens 100 can be mounted on a transmission electron microscopy grid. The membrane 105 can include a silicon device layer from a silicon-on-insulator (SOI) wafer. The silicon device layer can include a layer made of silicon that is part of a device. The membrane 105 can be immersed in a liquid medium and configured to operate in the liquid medium. The membrane 105 can have a non-zero in-plane curvature. For example, a coma-corrected device can include the membrane 105 with the non-zero in-plane curvature. In-plane curvature can include the curvature of the membrane surface. The optical device can include a plurality of optical functions for a plurality of light angles of incidence. For example, the plurality of optical functions can include a coma-corrected lens. The membrane 105 can include the plurality of optical functions for a plurality of light angles of incidence.

In some embodiments, the membrane 105 is a first membrane and the optical device includes a second membrane cascaded in series with (e.g., adjacent to, juxtaposed, next to, etc.) the first membrane for multi-surface applications. The second membrane cascaded in series with the first membrane can include a bilayer including a first membrane and a second membrane. The bilayer can include the second membrane adjacent to the first membrane. The bilayer can include the second membrane on top of the first membrane or a first membrane on top of the second membrane. In some embodiments, the membrane 105 is sandwiched between two reflective or partially-reflective layers to produce an optical cavity. This arrangement can increase the Q-factor of resonance. The membrane 105 can include the first surface 140 and the second surface 145. The first surface 140 can be coated with at least one of a solid (e.g., thin solid such as 1 nm to 10 μm thick), a liquid, or a polymeric film. For example, the first surface 140 can be coated with an anti-reflection coating, high reflection coating, or bio-compatible coating. The first surface 140 can be coated with a coating to provide structural support or protection.

In some embodiments, the plurality of apertures 110 is a first plurality of apertures. The membrane 105 can include a second plurality of apertures extending at least partially through the thickness 125 of the membrane 105. The membrane 105 can include the first surface 140 and the second surface 145. The first plurality of apertures can each have an opening in a plane defined by the first surface 140 and can lack an opening along a plane defined by the second surface 145. The second plurality of apertures can each have an opening in the plane defined by the second surface 145 and can lack an opening along the plane defined by the first surface 140.

The metalens 100 can be part of an optical device for reflection. The optical device can include a monolithic metasurface or metalens 100. The monolithic metasurface can include a metasurface made of a single material (e.g., crystalline silicon, etc.). The optical device can operate in an X-ray to ultraviolet spectral range. The optical device can include the metalens 100 or the membrane 105. The membrane 105 can include a plurality of apertures 110 extending at least partially through a thickness 125 of the membrane 105. The membrane 105 can be configured to structure (e.g., modify, change) incoming light 130 to produce modified light 135 that is reflected. The incoming light 130 can have a wavelength (e.g., wavelength of the incoming light). The incoming light 130 can have one or more wavelengths. The wavelength of the incoming light 130 in vacuum (e.g., vacuum wavelength, vacuum wavelength of the incoming light) can be in a range from X-ray light to EUV light to ultraviolet light. The X-ray light can be in a wavelength range of 0.3 nm to 3 nm (e.g., 0.3 nm, 1 nm, 2 nm, or 3 nm, inclusive). The EUV light can be in a wavelength range of 10 nm to 121 nm (e.g., 10 nm, 20 nm, 50 nm, 100 nm, or 121 nm, inclusive). Ultraviolet (UV) light can be in a wavelength range of 100 nm to 400 nm (e.g., 100 nm, 150 nm, 200 nm, 250 nm, 300 nm, 350 nm, or 400 nm, inclusive). The wavelength of the incoming light 130 in vacuum can be in a wavelength range of 0.3 nm to 400 nm (e.g., 0.05 nm, 1 nm, 10 nm, 20 nm, 50 nm, 100 nm, or 400 nm, inclusive). The wavelength of the incoming light 130 in vacuum can be X-ray light, EUV light, or UV light. Structuring the incoming light 130 can include modifying the phase profile, amplitude profile, or polarization profile of the incoming light 130. For example, the modified light 135 that is reflected can have a different phase profile, amplitude profile, or polarization profile than that of the incoming light 130. Each of the plurality of apertures 110 can have a diameter 120 (e.g., width, hole diameter, etc.).

An index of refraction within a first aperture of the plurality of apertures 110 can be greater than an index of refraction of the membrane 105. For example, the index of refraction within the first aperture of the plurality of apertures 110 can include a high index of refraction. The index of refraction of the membrane 105 can include a low index of refraction. The index of refraction of the membrane 105 can be lower than the index of refraction within the first aperture of the plurality of apertures 110. The index of refraction within the first aperture can correspond to an index of refraction of the at least one of the vacuum, the gaseous medium, the liquid medium, or the solid medium. The index of refraction can include the ratio of the speed of light in a vacuum to the speed of light in a medium (e.g., gaseous medium, liquid medium, solid medium, etc.).

In some embodiments, the plurality of apertures 110 can include via-holes or through-holes. The membrane 105 can include a first surface 140 and a second surface 145. The plurality of apertures 110 can each have an opening (e.g., nano-opening, nanohole, etc.) in a plane defined by the first surface 140 and can each have another opening (e.g., nano-opening, nanohole, second opening, etc.) in a plane defined by the second surface 145. For example, the plurality of apertures 110 can go through the first surface 140 and/or through the second surface 145. The diameter 120 of the plurality of apertures 110 can control the reflected phase of light. The openings can have radial symmetry or non-radial symmetry. The cross-sectional profile of the openings can vary through the depth of the openings. The plurality of apertures 110 can be disjoint. For example, each of the plurality of apertures can be completely separated from each other. The plurality of apertures 110 can be formed via etching or through an etching process. The membrane 105 can be formed through an etching process as opposed to an additive manufacturing process to create the membrane 105. The plurality of apertures 110 can be located within the membrane 105 as opposed to holes being located within pillars.

In some embodiments, the membrane 105 can be configured to operate in reflection of the modified light 135 as at least one of a converging reflector, a diverging reflector, a cylindrical reflector, a corrector of optical aberrations of a second optical element, a diffraction grating, or a waveplate. For example, the membrane 105 can operate in reflection by reflecting incoming light 130 away from the membrane 105. The membrane 105 can be configured to operate in reflection as a corrector of optical aberrations of a second optical element. The membrane 105 can be configured to operate in reflection as a diffraction grating. The membrane 105 can be configured to operate in reflection as a waveplate (e.g., retarder). For example, the membrane 105 can operate as a waveplate by altering the polarization of the incoming light 130. The membrane 105 can also operate as a spatially-varying waveplate by altering the polarization of incoming light 130 in a spatially-varying manner.

In some embodiments, one or more optical properties is constant at a plurality of incident wavelengths. The one or more optical properties of the membrane 105 can be constant at a plurality of incident wavelengths. The one or more optical properties of the optical device can be constant at a plurality of incident wavelengths. A phase profile of the reflected modified light 135 can produce focusing of incident light at a plurality of wavelengths with a same focal length. For example, the optical device can exhibit achromatic behavior. The phase profile of the transmitted or reflected modified light 135 can produce diffracted orders with a same diffraction angle at a plurality of wavelengths. For example, the optical device can exhibit achromatic grating behavior.

In some embodiments, the modified light 135 that is reflected includes light with at least one of a modified optical phase profile, modified amplitude profile, or modified polarization profile. The incoming light can have a first optical phase profile and the modified light can have a second optical phase profile. The first optical phase profile can be different from the second optical phase profile. The incoming light can have a first amplitude profile and the modified light can have a second amplitude profile. The first amplitude profile can be different from the second amplitude profile. The incoming light can have a first polarization profile and the modified light can have a second polarization profile. The polarization profile can include the geometric orientation of light waves. The first polarization profile can be different from the second polarization profile. The incoming light can have a first wavelength and the modified light can have a second wavelength. The first wavelength can be different from the second wavelength. The first wavelength can be the same as the second wavelength.

In some embodiments, the incoming light 130 can exert an optical force on the metalens 100. In some embodiments, the modified light 135 can exert an optical force on the metalens 100. In some embodiments, the incoming light 130 does not exert an optical force on the metalens 100. In some embodiments, the modified light 135 does not exert an optical force on the metalens 100.

In some embodiments, each of the plurality of apertures 110 can have non-cylindrical symmetry. For example, the plurality of apertures 110 can include rectangular prism structures. A cross-sectional profile of a first aperture of the plurality of apertures 110 can be constant over a length of the first aperture. In some embodiments, a cross-sectional profile of a first aperture of the plurality of apertures 110 can vary over a length of the first aperture.

In some embodiments, the plurality of apertures 110 can be periodically placed on the membrane 105. For example, the plurality of apertures 110 can be placed periodically in a square unit cell separated by the placement distance 115. Each of the plurality of apertures 110 can be separated by the placement distance 115. The plurality of apertures 110 can be periodically space in the membrane 105. The plurality of apertures 110 can be placed at regular occurring intervals.

In some embodiments, the plurality of apertures 110 can be aperiodically placed on the membrane 105. For example, the plurality of apertures 110 have a varying placement distance 115 on the membrane 105. In some embodiments, the plurality of apertures 110 can be quasirandomly placed on the membrane 105. For example, the plurality of apertures 110 have a varying placement distance 115 according to a quasirandom pattern on the membrane 105. This pattern can be generated to reduce the strength of undesirable diffracted orders.

In some embodiments, the placement distance 115 (e.g., such as aperture edge to aperture edge distance, or aperture center to aperture center distance) between each of the plurality of apertures 110 can be subwavelength relative to the wavelength of the incoming light 130. For example, the placement distance 115 between each of the plurality of apertures 110 can be less than the wavelength of the incoming light 130 in vacuum. Subwavelength can include a multiple (e.g., 0.1 times, 0.2 times, 0.3 times, 0.4 times, 0.5 times, 0.6 times, 0.7 times, 0.8 times, 0.9 times, etc.) of the wavelength of the incoming light 130 that is less than the wavelength of the incoming light 130. The placement distance 115 between each of the plurality of apertures 110 can be less than, greater than, or equal to the wavelength of the incoming light 130. The placement distance 115 between each of the plurality of apertures 110 can be a distance between a first aperture outer radius and a second aperture outer radius. The outer radius of each of the plurality of apertures 110 can be the aperture edge. The placement distance 115 between each of the plurality of apertures can be a center of a first aperture and a center of a second aperture. The center of an aperture can be equidistant from the aperture edge. In some embodiments, the placement distance 115 between each of the plurality of apertures 110 can be relative to the wavelength of the incoming light 130. For example, the placement distance 115 between each of the plurality of apertures 110 can be equal to or more than the wavelength of the incoming light 130 in vacuum.

In some embodiments, the thickness 125 of the membrane 105 remains constant over a length or a width of the membrane 105. For example, if the thickness 125 of the membrane 105 is 220 nm, this value can remain constant across the entirety of the membrane 105. The thickness 125 of the membrane 105 can vary along a length or a width of the membrane 105.

In some embodiments, the membrane 105 is mounted onto at least one of a flat solid substrate or a curved solid substrate to provide structural support. For example, the metalens 100 can be mounted on a thin-film mirror. The membrane 105 can include a silicon device layer from a silicon-on-insulator (SOI) wafer. The silicon device layer can include a layer made of silicon that is part of a device. The membrane 105 can be immersed in a liquid medium and configured to operate in the liquid medium. For example, a coma-corrected device can include the membrane 105 with the non-zero in-plane curvature. In-plane curvature can include the curvature of the membrane surface. The optical device can include a plurality of optical functions for a plurality of light angles of incidence. For example, the plurality of optical functions can include a coma-corrected lens. The membrane 105 can include the plurality of optical functions for a plurality of light angles of incidence.

In some embodiments, the membrane 105 is a first membrane and the optical device includes a second membrane cascaded in series with (e.g., adjacent to, juxtaposed, next to, etc.) the first membrane for multi-surface applications. The second membrane cascaded in series with the first membrane can include a bilayer including a first membrane and a second membrane. The bilayer can include the second membrane adjacent to the first membrane. The bilayer can include the second membrane on top of the first membrane or a first membrane on top of the second membrane. In some embodiments, the membrane 105 is sandwiched between two reflective or partially-reflective layers to produce an optical cavity. This arrangement can increase the Q-factor of resonance. The membrane 105 can include the first surface 140 and the second surface 145. The first surface 140 can be coated with at least one of a solid (e.g., thin solid such as 20 to 100 μm thick), a liquid, or a polymeric film. For example, the first surface 140 can be coated with an anti-reflection coating, high reflection coating, or bio-compatible coating. The first surface 140 can be coated with a coating to provide structural support or protection.

In some embodiments, the plurality of apertures 110 is a first plurality of apertures. The membrane 105 can include a second plurality of apertures extending at least partially through the thickness 125 of the membrane 105. The membrane 105 can include the first surface 140 and the second surface 145. The first plurality of apertures can each have an opening in a plane defined by the first surface 140 and can lack an opening along a plane defined by the second surface 145. The second plurality of apertures can each have an opening in the plane defined by the second surface 145 and can lack an opening along the plane defined by the first surface 140.

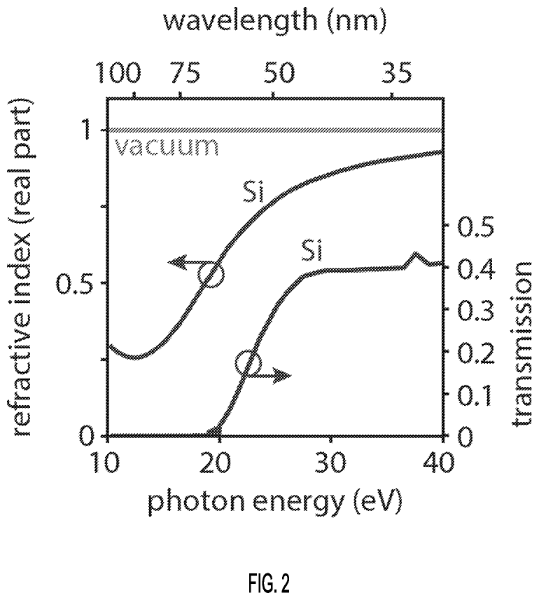

FIG. 2 illustrates a plot of a photon energy-dependent refractive index of crystalline silicon and a plot of an intensity transmission of the membrane 105. The membrane 105 can include a silicon membrane (e.g., a membrane made of silicon). The membrane 105 can have a thickness of 220 nm. The membrane 105 can be chosen as a base material and cylindrical holes can be chosen as a polarization-independent guiding structures. Both the real and imaginary parts of the index of refraction of the silicon membrane 105 are represented in FIG. 2.

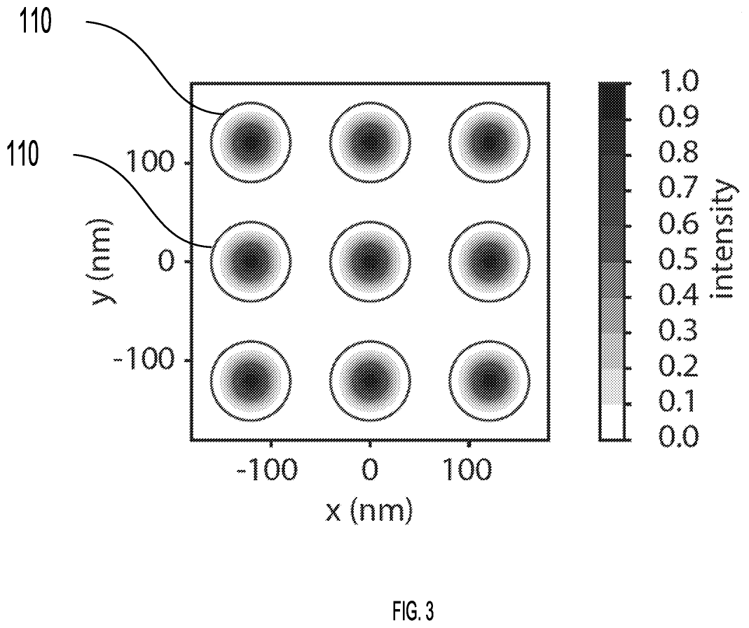

FIG. 3 illustrates a finite difference time domain simulation of a transverse beam intensity profile of EUV-guiding in 80 nm diameter 120 holes through the membrane 105. The finite difference time domain simulation can be a numerical analysis technique. The beam intensity profile can be the variation of intensity as a function of distance from a center of the beam. The membrane 105 can include a silicon membrane (e.g., a membrane made of silicon). The membrane 105 can have a thickness of 220 nm. This simulation can be performed on a perforated silicon membrane 105 to emphasize the vacuum-guiding effect that the plurality of apertures 110 have. The vacuum-guiding effect can be the tendency of incoming light 130 to transmit through the plurality of apertures 110. 87% of the energy of a plane wave of incoming light 130 with a 50 nm wavelength (25 eV photon energy) can be transmitted within the plurality of apertures 110 of the membrane 105. In this simulation, the plurality of apertures 110 can cover 34% of the area of the membrane 105.

A rigorous coupled-wave analysis (RCWA) can be conducted to simulate the transmission and transmission phase of different hole diameters 120, membrane thicknesses 125, and aperture placement distances 115. A radius and wavelength-dependent phase profile of a lens can be described by:

$$φ ( r , λ ) = - \frac{2 π}{λ} ( \sqrt{{r}^{2} + {f}^{2}} - f ) , \qquad ( 1 )$$

where f is the lens focal length, r is the radial coordinate on the metalens plane, and λ is the wavelength of the incoming light 130.

To enforce this phase profile, the metalens surface can be partitioned into pixels of subwavelength or wavelength-scale in-plane size. The meta-element for each pixel can be selected based on its radial position r. These meta-atoms can be selected from a “library” (e.g., a collection) of meta-atoms, where the optical response (e.g., phase response, amplitude response, polarization response, etc.) of each meta-element has been simulated in advance. This technique can be used to forward-design a focusing vacuum-guiding EUV metasurface.

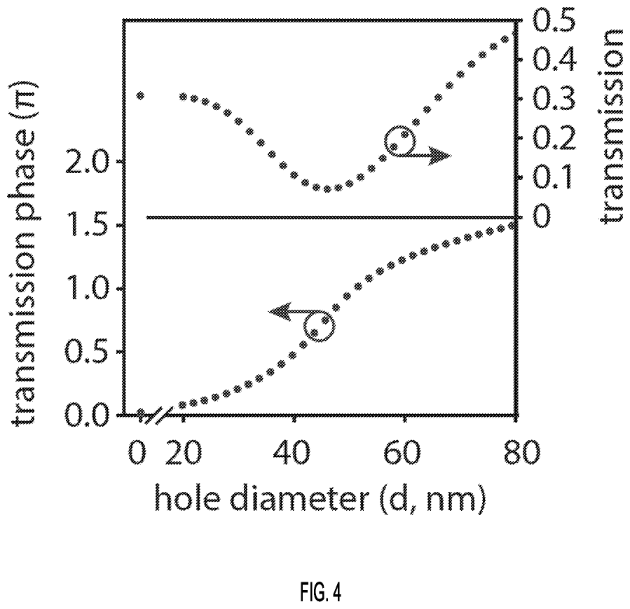

FIG. 4 illustrates plots of a hole diameter-dependent intensity transmission (top plot) and transmission phase (bottom plot). This plot can encompass the meta-atom library with a wavelength of λ=50 nm being chosen as a compromise between the vacuum-silicon index of refraction contrast and material absorption of light energy. Hole-diameter dependent transmission phases for different square unit cell sizes can be calculated using RCWA. The membrane 105 for the meta-atom library can have a periodic square array of holes. In this case, the complex index of refraction can be n(λ=50 nm)=0.77+0.02i). A square unit cell of 120 nm in size can correspond to 1.85λ of the wavelength of light with a wavelength of 50 nm in vacuum in the membrane material. The square unit cell can be the distance between the plurality of apertures 110 arranged in a square array. To forward-design a focusing vacuum-guiding EUV metasurface, the wavelength-dependent phase profile can be matched to a phase profile at each radius r with a meta-atom schematic from the library seen in FIG. 4.

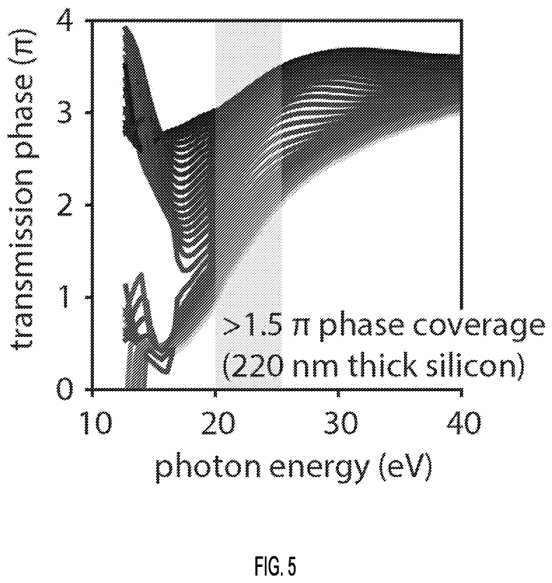

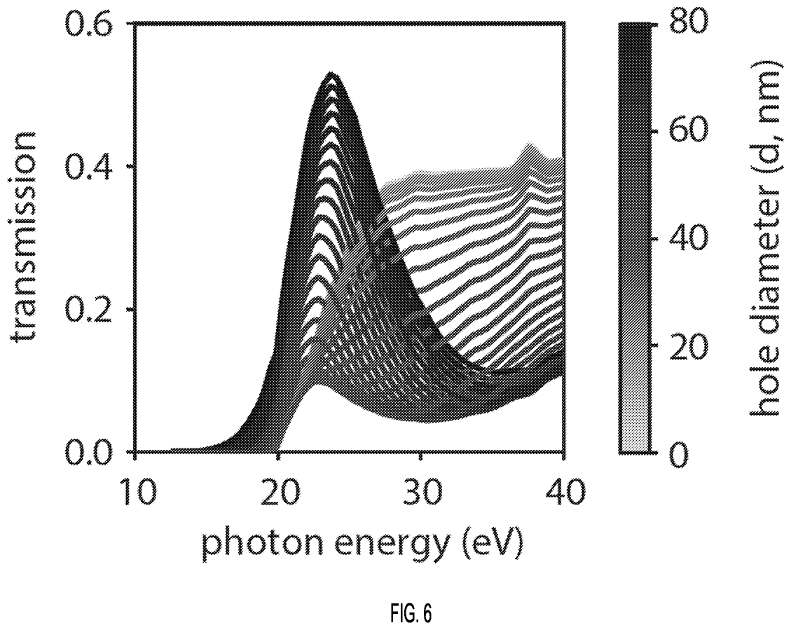

Using RCWA, the results of a transmission and transmission phase simulation of a membrane 105 are shown in FIG. 5 and FIG. 6. The membrane 105 can be composed of crystalline silicon. The thickness 125 of the membrane 105 can be 220 nm. A square unit cell of the membrane 105 can be 120 nm. The diameter 120 of the plurality of apertures 110 on the membrane 105 can range from 20 nm to 80 nm. FIG. 5 illustrates a plot of a photon energy and hole diameter-dependent transmission phase of holes while FIG. 6 illustrates a plot of a photon energy and hole diameter-dependent intensity transmission of holes. A 1.5× transmission phase coverage can coincide with more than 10% transmission between wavelengths of 50 nm and 62 nm for the incoming light 130.

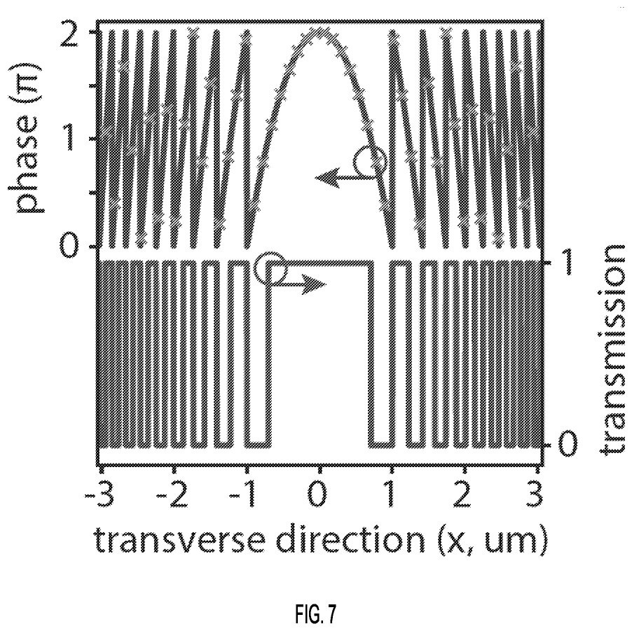

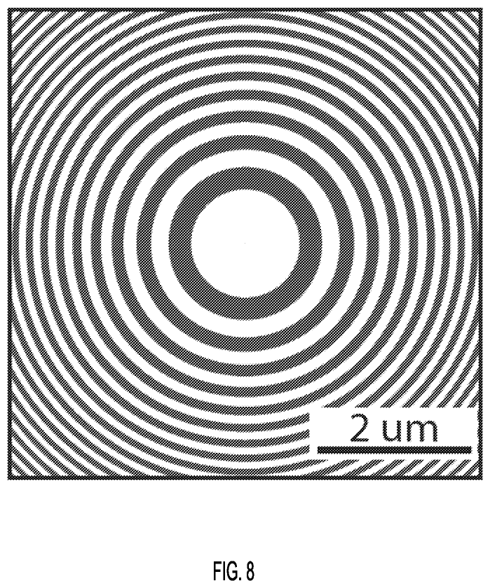

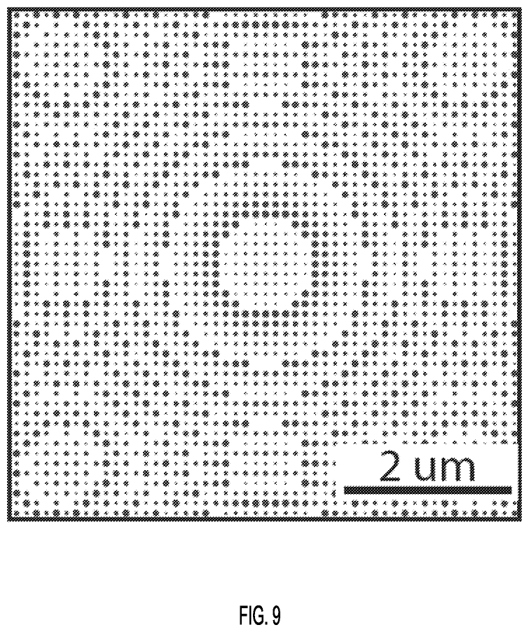

FIG. 7 illustrates a plot of an ideal radial phase profile of a metalens (top plot) compared to the intensity profile of a binary intensity Fresnel zone plate (bottom plot). The Fresnel zone plate can be a zone plate composed of a set of concentric rings that alternate between being opaque and transparent. A metasurface and a binary absorption zone plate with the focal length f=10 μm and diameter d=6.1 μm can be designed to explore the benefits of EUV metasurfaces compared to existing zone plates. The results of this design are shown in FIG. 7. Parameters that for an ideal radial phase profile of a metalens and a binary intensity Fresnel zone plate can be a maximum numerical aperture NA=0.3, focal length f=10 μm and size of 6 μm×6 μm designed for an incoming light 130 with a wavelength of 50 nm. The ideal radial phase profile of the metalens is shown on a top half of FIG. 7 while the binary intensity Fresnel zone plate results are shown on a bottom half on FIG. 7. The 2-D design of the radial phase profile can be seen in FIG. 8 while the 2-D design of the intensity profile of a binary intensity Fresnel zone plate can be seen in FIG. 9.

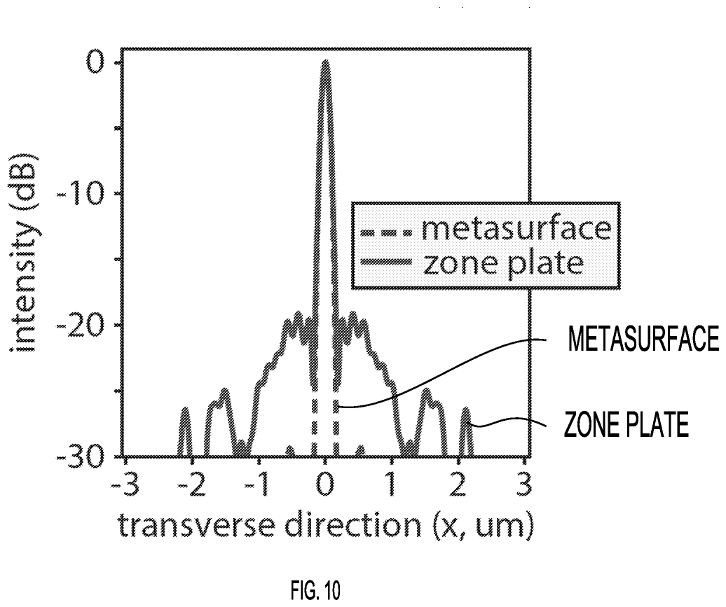

FIG. 10 illustrates a model of transverse intensity cuts through the focus generated by the zone plate in FIG. 8 and the metalens in FIG. 9. A transmission of a linearly polarized Gaussian beam can be simulated. The Gaussian beam can be a beam characterized by a Gaussian intensity profile. The Gaussian beam can have a beam waist

$${ω}_{0}^{illumination} = 2 µm , \\ measured as I ( {ω}_{0} ) = \frac{I ( 0 )}{{e}^{2}} , \\ beam diameter d = 2 {ω}_{0}^{illumination} = 4 µm .$$

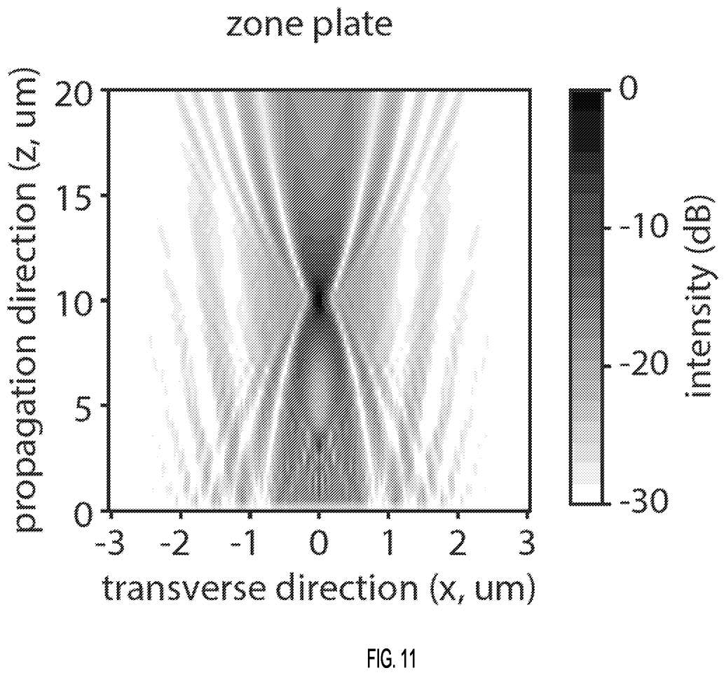

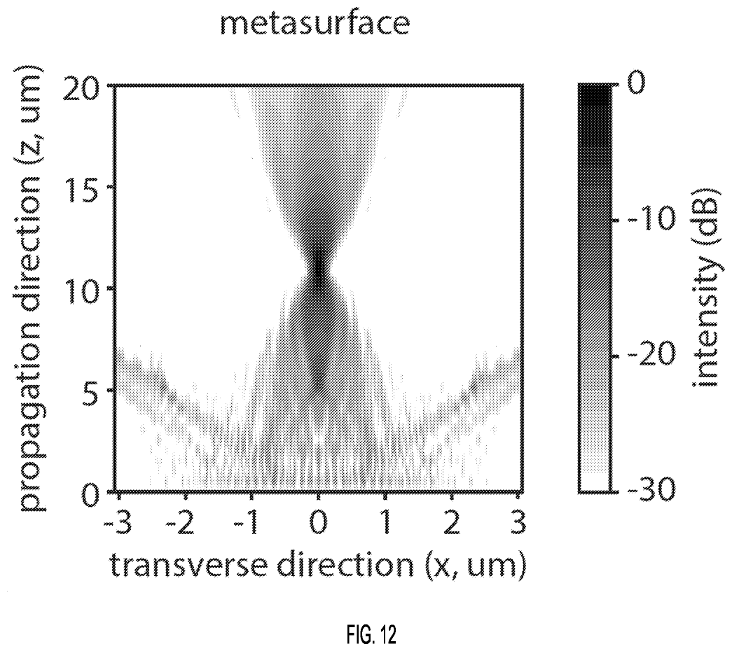

A Gaussian beam incident can be simulated through both the zone plate and the metalens on a perforated silicon membrane and a 3 wavelengths-thick vacuum spacer region before and after the membrane 105 using finite difference time domain modeling. In this vacuum spacer region, all near-fields can decay, thus subsequent evolution can be modelled using the Huygens-Fresnel principle. Using a Gaussian beam can decrease unphysical edge effects and results in an effective numerical aperture of NA_{eff}˜0.20. An evolution of both focused beams can be seen in FIG. 11 and FIG. 12. FIG. 11 illustrates a model of 2-D light intensity evolution of the zone plate of FIG. 8 focusing a Gaussian beam while FIG. 12 illustrates a model of 2-D light intensity evolution of the metalens of FIG. 9 focusing a Gaussian beam.

For these conditions of the linearly polarized Gaussian beam, a perfect lens could create a minimum beam waist

$${ω}_{0}^{ideal} = 85 nm$$

at its focus. The binary zone plate and the metasurface both can approach this diffraction limit with minimum beam waists of

$${ω}_{0}^{zone plate} = 91 nm and {ω}_{0}^{metasurface} = 94 nm ,$$

receptively. A maximum intensity of the metasurface focus can exceed that of the zone plate by 9%. In FIG. 11, the metasurface can model the lens phase profile accurately with no sidelobes visible in its focal plane while FIG. 12 has the zone plate focus showing clear sidelobes. A sidelobe can be unwanted radiation in undesired directions. FIG. 10 illustrates a model of transverse intensity cuts through the focus generated by the zone plate in FIG. 8 and the metalens in FIG. 9 and can highlight the sidelobe behavior visible in FIG. 12. An illumination by a Gaussian beam can have a 4 μm 1/e² diameter. The sidelobes present around the focus in FIG. 12 are more than 10 dB smaller for the metasurface in FIG. 11 compared to the zone plate in FIG. 12. A unit cell size on the order of the wavelength for manufacturability can result in a weak first order as generated by grating that can be made up by the unit cells. The first order can be diffracted to a large angle (25°) and can therefore, rarely cause imaging distortion as it may not reach a detector or can be blocked before detection.

Free-standing metasurface membranes (e.g., metalens 100) can be fabricated from silicon-on-insulator wafers. The metasurface membrane can include the plurality of apertures 110. Each of the plurality of apertures 110 can have a diameter 120 of 20 nm. The plurality of apertures 110 can be separated by links (e.g., links of silicon) with a thickness of 40 nm. The links can include the placement distance 115. The links can include aperture edge to aperture edge distance. The diameter of each of the plurality of apertures 110 and the thickness of the links of silicon can contribute to membrane stability. To increase the stability of the membrane 105, holes can be omitted on a 1 μm thick grid spaced by 10 μm×10 μm. A silicon-on-insulator wafer can be composed of a 220 nm thick silicon device layer, 3 μm thick buried oxide layer, and 725 μm thick silicon carrier layer. A silica layer can be deposited by using plasma-enhanced chemical vapor deposition. A layer of positive electron beam lithography resist can be spin-coated on top of the silica layer. A metalens pattern can be exposed using electron-beam lithography and can be developed. A metalens pattern can be transferred to the silica layer using inductively coupled plasma reactive ion etching. The metalens pattern can be transferred to the silicon device layer by using non-Bosch reactive ion etching. This step can also diminish the silica hard mask. After defining the metalens pattern, the membrane area can be defined on the backside of the wafer using a spin-coated positive photoresist layer and maskless aligner. After exposure and development, the silicon carrier layer can be removed and the buried oxide layer (e.g., buffered hydrogen fluoride wet etch) can also be removed.

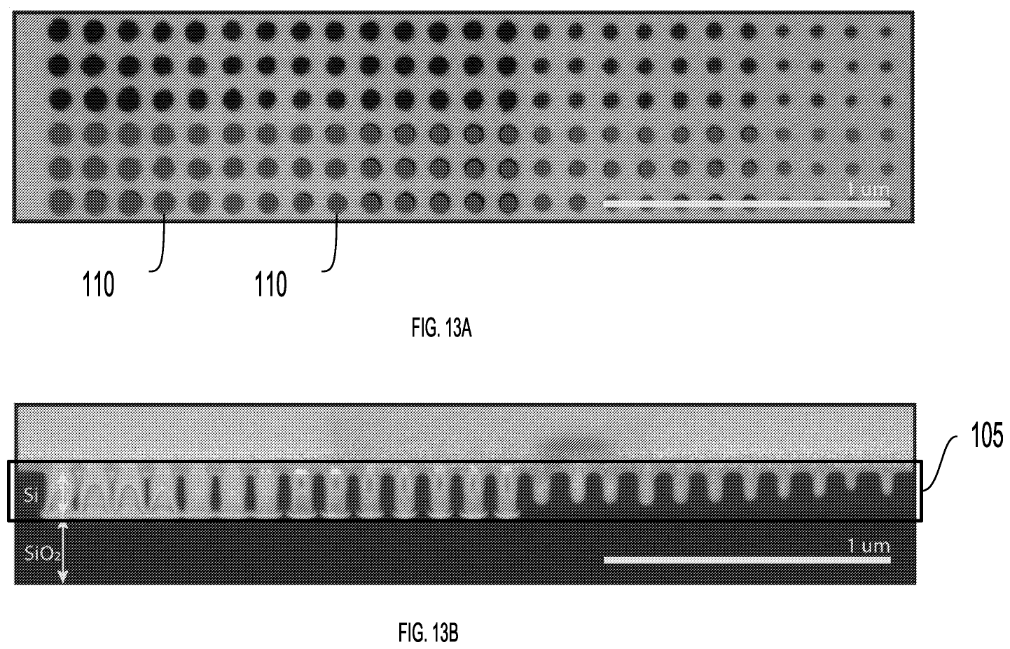

The focal length of f=10 mm can be realized and metasurfaces with a 1 mm diameter 120 and a maximum numerical aperture NAₘₐₓ=0.05 can be fabricated and can be designed for 50 nm wavelength. FIG. 13A illustrates an overhead view of a fabricated metalens. The fabricated metalens can include the plurality of apertures 110. FIG. 13A can be taken by scanning-electron microscopy (SEM). The plurality of apertures 110 can have varying diameters 120 as seen in FIG. 13.

FIG. 13B illustrates a cross-sectional view of a fabricated metalens. The membrane 105 is marked out by a rectangle in FIG. 13B. The membrane 105 can be composed of crystalline silicon. The membrane 105 can be fabricated from a silicon-on-insulator wafer. An insulator can be silicon dioxide. FIG. 13B can be taken by focused ion beam milling and scanning-electron microscopy (SEM). Designed hole diameters 120 can be achieved by using both diameter-dependent electron beam lithography doses as well as diameter-dependent fabrication offsets. FIG. 13B shows that a smallest hole diameter 120 can be partially etched.

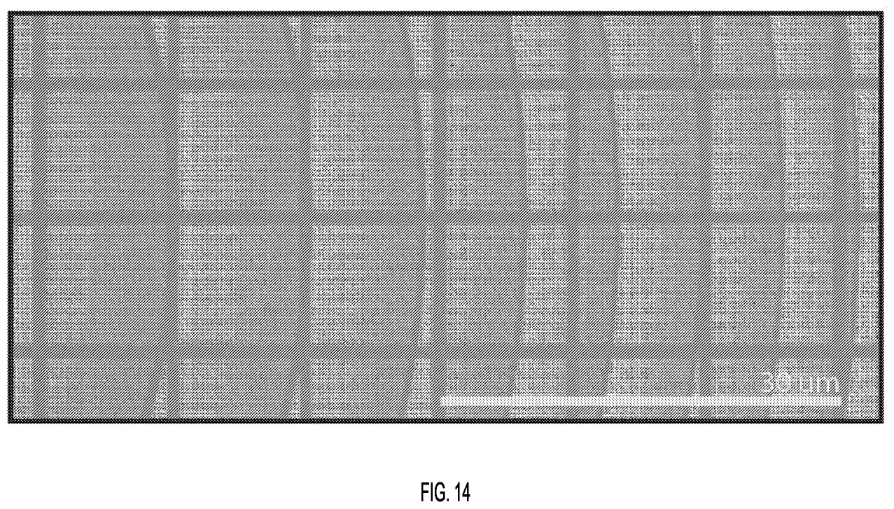

FIG. 14 illustrates a large-area picture of the metalens 100 in FIGS. 13A-13B. FIG. 14 can be taken by SEM. These images can be taken after metasurface etching but before membrane isolation. Areas without holes can increase the stability of the metalens 100. The areas without holes can be marked out by a rectangular grid as seen in FIG. 14.

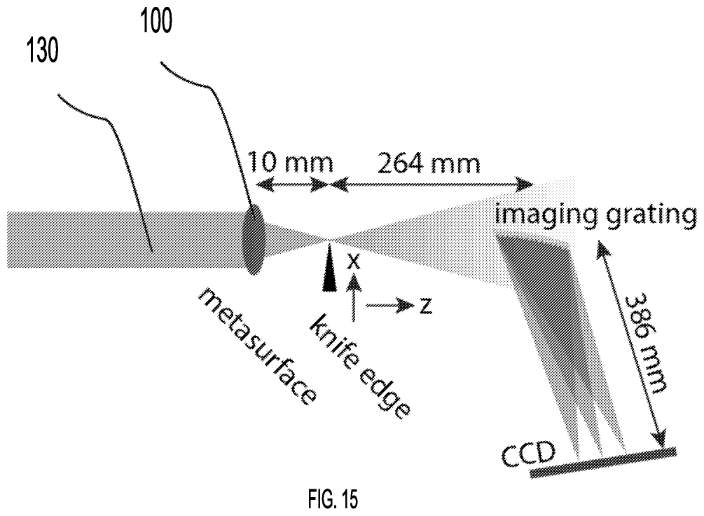

FIG. 15 illustrates an experimental demonstration set-up of EUV metalens focusing. Broadband EUV radiation can be generated from near-infrared laser pulses via high harmonic generation. A final high harmonic generation radiation (e.g., incoming light 130) can contain spectral components from 1 eV to above 42 eV. The metalens 100 can interact with the incoming light 130. After the metalens 100, a knife-edge scan can be performed using a razorblade mounted on a piezo nanopositioner. A transmitted radiation can be dispersed spectrally using a toroidal grating. Radiation can be detected using a charge-coupled-device camera. The EUV radiation can be focused using the metalens 100.

The effect of the metasurface at the design wavelength can be isolated by dispersing the spectral components of the pulse train using a toroidal grating along the horizontal axis of the CCD. The CCD can then detect a hyperspectral image of a beam profile created by the metalens 100 close to a focus position.

Astigmatism introduced by the toroidal grating can be excluded using a knife-edge scan to evaluate the performance of the metalens 100. A part of the focused beam can be blocked by introducing a razorblade perpendicularly to its propagation direction and can record the knife-position dependent transmitted intensity. Since focusing concentrates a beam intensity along the transversal direction, a negative spatial derivative of a recorded intensity can reveal the beam profile.

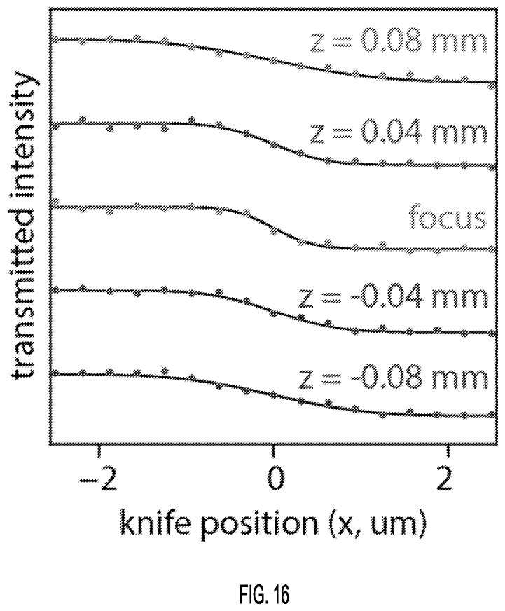

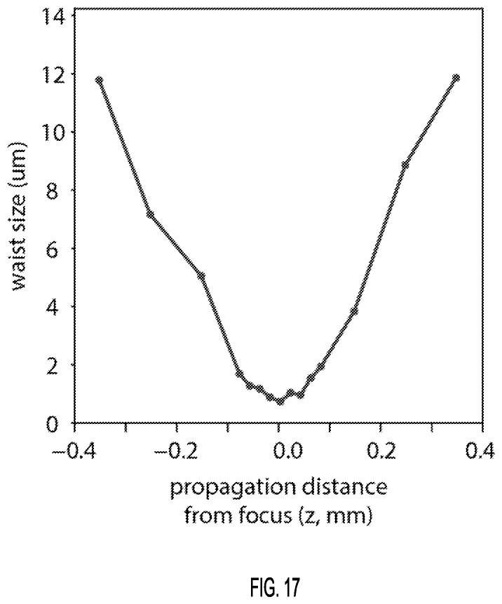

FIG. 16 illustrates a plot of different knife positions along the propagation direction of a beam after the metalens 100 of an experimental demonstration of EUV metalens focusing. For different positions along the propagation direction of the beam after the metalens 100, a photon flux can be integrated. As the razorblade moves into a focus, it can block parts of a transmitted radiation and can decrease a transmitted flux. A large negative derivative of the transmitted flux can represent a small focus. A clear maximum of the negative spatial derivative can be observed and can indicate a focal plane. Corresponding beam sizes can be extracted by assuming a Gaussian beam and an error function can be fitted to data at each position along the propagation direction. FIG. 17 illustrates a plot of propagation-direction dependent focus sizes of an experimental demonstration of EUV metalens focusing. The metalens 100 can focus the illuminating beam (beam waist

$${ω}_{0}^{illumination} \approx 0.55 mm ,$$

effective numerical aperture MA_{eff}≈0.5) down to at least

$${ω}_{0}^{metasurface} = 0.7 um ,$$

which is within 1.6 times the diffraction limit

$$( {ω}_{0}^{diffraction limit} = 0.45 um ) .$$

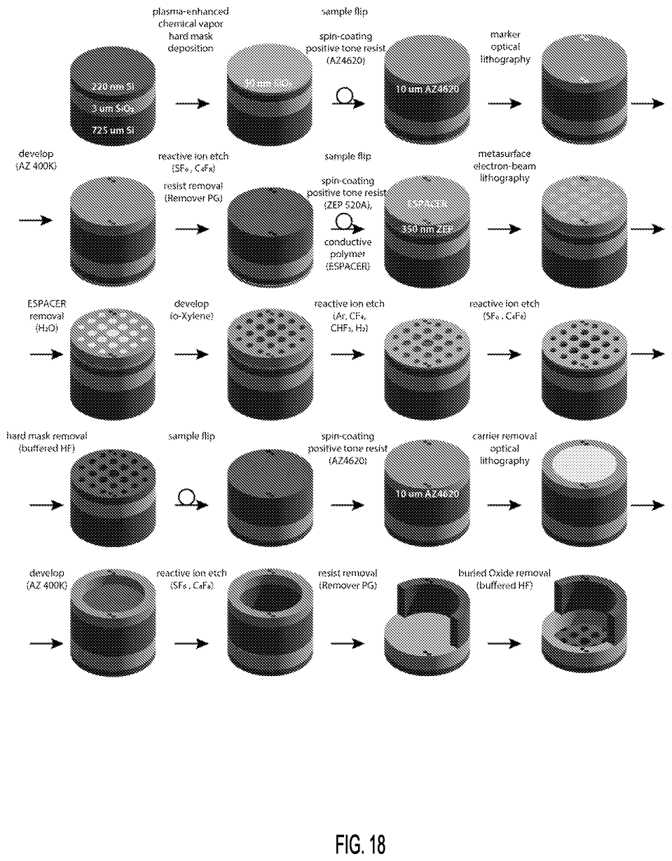

FIG. 18 illustrates a fabrication process for the metalens 100. In brief overview, a SiO₂ hard mask layer and electron beam resist layer can be deposited on a Silicon on Insulator substrate. The resist layer can be patterned with electron-beam lithography and the pattern can be transferred to the SiO₂ layer through dry etching using the resist as an etch mask. Next, the electron beam resist can be removed. Next, the holes can be etched into the silicon membrane using the patterned SiO₂ as a hard mask. Then the chip can be flipped. The reverse side of the chip can be coated with optical resist and large circular patterns can be written using a maskless aligner. The exposed silicon in the circle can be dry etched and thinned and the then-exposed SiO₂ can be wet etched using the optical resist as an etch mask. This can produce a thin membrane at the base of the circular patterns.

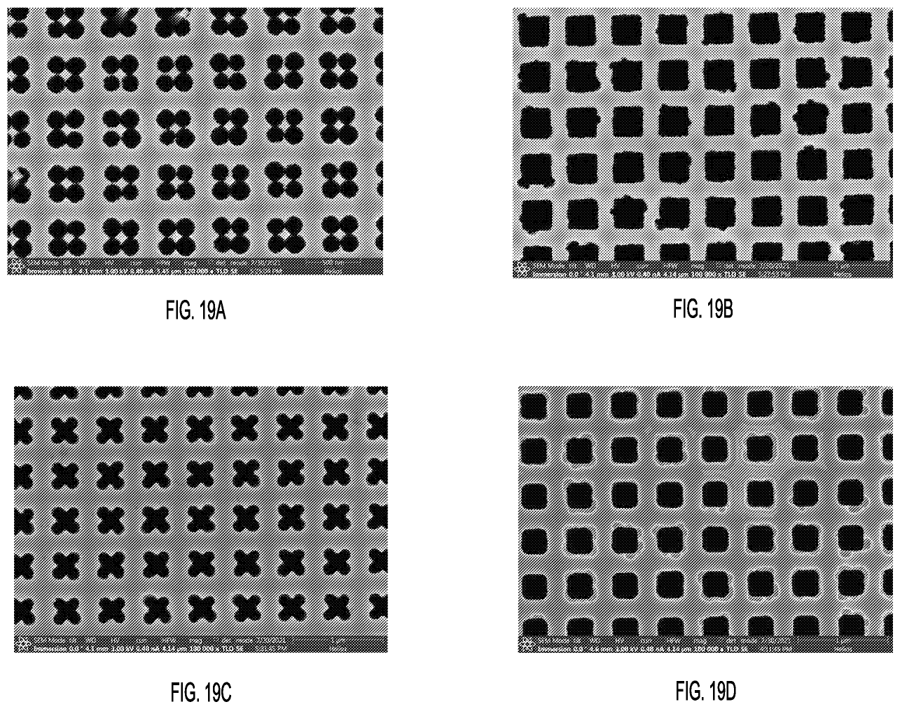

FIGS. 19A-19D illustrate scanning electron micrographs of metalens arrays with various hole shapes. The metalens arrays can include a plurality of metalens 100. The plurality of apertures 110 can have various shapes. For example, the plurality of apertures 110 can have a shape such as a square, ellipse, circle, cross, square with rounded corners, rectangle, triangle, or other shape. The plurality of apertures 110 can have anisotropic structures to allow for the optical device or metalens 100 to have polarization functionality. Polarization functionality can include the capability of changing the polarization of incoming light (e.g., reflecting or transmitting polarized light) or having optical functions that differ based on the polarization of incoming light. FIG. 19A illustrates a periodic array of hole clusters (e.g., clusters of holes or apertures). The clusters of holes can include a plurality of apertures 110. For example, the clusters of holes can include four holes arranged with the center of each hole at the corner of a square. The clusters of holes can be separated by the placement distance 115. The clusters of holes can include the plurality of apertures 110 extending at least partially through the thickness 125 of the membrane 105. FIG. 19B illustrates a periodic array of square apertures. The square apertures can include the plurality of apertures 110 extending at least partially through the thickness 125 of the membrane 105. The plurality of apertures 110 can be separated by the placement distance 115. FIG. 19C illustrates a periodic array of cross-shaped apertures. The cross-shaped apertures can include the plurality of apertures 110 extending at least partially through the thickness 125 of the membrane 105. The plurality of apertures 110 can be separated by the placement distance 115. FIG. 19D illustrates a periodic array of square apertures. The square apertures can include the plurality of apertures 110 extending at least partially through the thickness 125 of the membrane 105. The plurality of apertures 110 can be separated by the placement distance 115.

A method of the present disclosure can include providing an optical device. The optical device can include a membrane. The membrane can include a plurality of apertures extending at least partially through a thickness of the membrane. The membrane can be configured to structure incoming light having a wavelength to produce modified light. The wavelength of the incoming light can be in a range from a wavelength of X-ray light to a wavelength of ultraviolet light. The membrane can be configured to transmit the modified light through the membrane or reflect the modified light away from the membrane. An index of refraction within a first aperture of the plurality of apertures can be greater than an index of refraction of the membrane.

As used herein, the singular terms “a,” “an,” and “the” may Include plural referents unless the context clearly dictates otherwise. Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementations,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Elements other than ‘A’ and ‘B’ can also be included.

The systems and methods described herein may be embodied in other specific forms without departing from the characteristics thereof. The foregoing implementations are illustrative rather than limiting of the described systems and methods.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. An optical device, comprising:
a membrane comprising a plurality of apertures extending at least partially through a thickness of the membrane, configured to:
structure incoming light having a wavelength to produce modified light, wherein the wavelength of the incoming light is in a range extending from a wavelength of X-ray light to a wavelength of ultraviolet light; and
transmit the modified light through the membrane;
wherein an index of refraction within a first aperture of the plurality of apertures is greater than an index of refraction of the membrane.

2. The optical device of claim 1, wherein at least one of a vacuum, a gaseous medium, a liquid medium, or a solid medium, is disposed in the first aperture of the plurality of apertures.

3. The optical device of claim 2, wherein the index of refraction within the first aperture corresponds to an index of refraction of the at least one of the vacuum, the gaseous medium, the liquid medium, or the solid medium.

4. The optical device of claim 1, wherein the membrane comprises crystalline silicon.

5. The optical device of claim 1, wherein the incoming light comprises an extreme ultraviolet wavelength in a range of 10 nm to 121 nm.

6. The optical device of claim 1, wherein:
the membrane comprises a first surface and a second surface; and
the plurality of apertures each has an opening in a plane defined by the first surface and has another opening in a plane defined by the second surface.

7. The optical device of claim 1, wherein in transmitting the modified light, the membrane is configured to operate as at least one of a converging lens, a diverging lens, a cylindrical lens, a corrector of optical aberrations of a second optical element, a diffraction grating, or a waveplate.

8. The optical device of claim 1, wherein at least one optical property is constant at a plurality of incident wavelengths.

9. The optical device of claim 1, wherein a phase profile of the modified light that is transmitted produces focusing of incident light at a plurality of wavelengths with a same focal length.

10. The optical device of claim 1, wherein a phase profile of the modified light that is transmitted produces diffracted orders with a same diffraction angle at a plurality of wavelengths.

11. The optical device of claim 1, wherein the modified light includes light with at least one of a modified optical phase profile, modified amplitude profile, or modified polarization profile.

12. The optical device of claim 1, wherein the incoming light has a first polarization profile and the modified light has a second polarization profile.

13. The optical device of claim 1, wherein each of the plurality of apertures has non-cylindrical symmetry.

14. The optical device of claim 1, wherein:
a cross-sectional profile of the first aperture of the plurality of apertures is constant over a length of the first aperture.

15. The optical device of claim 1, wherein the plurality of apertures are periodically placed on the membrane.

16. The optical device of claim 1, wherein the plurality of apertures are quasirandomly placed on the membrane.

17. The optical device of claim 1, wherein the thickness of the membrane is constant over a length and a width of the membrane.

18. The optical device of claim 1, wherein the membrane is a layer of silicon from a silicon-on-insulator (SOI) wafer.

19. An optical device, comprising:
a membrane comprising a plurality of apertures extending at least partially through a thickness of the membrane, configured to:
structure incoming light having a wavelength to produce modified light, wherein the wavelength of the incoming light is in a range extending from a wavelength of X-ray light to a wavelength of ultraviolet light; and
reflect the modified light away from the membrane;
wherein an index of refraction within a first aperture of the plurality of apertures is greater than an index of refraction of the membrane.

20.-27. (canceled)

28. The optical device of claim 19, wherein a phase profile of the modified light that is reflected produces diffracted orders with a same diffraction angle at a plurality of wavelengths.

29.-36. (canceled)
